(19) United States
(12) Patent Application Publication
(10) Pub. No.: US 2026/0136900 A1
(43) Pub. Date: May 14, 2026

(54) CARBON-DOPED PVD DEPOSITED COBALT LINER LAYER FOR IMPROVED CU REFLOW

(71) Applicant: Applied Materials, Inc., Santa Clara, CA (US)

(72) Inventors: Sang-heum Kim, Mountain View, CA (US); Yong Jin Kim, Albany, CA (US); Fuhong Zhang, San Jose, CA (US)

(73) Assignee: Applied Materials, Inc., Santa Clara, CA (US)

(21) Appl. No.: 19/363,829

(22) Filed: Oct. 21, 2025

Related U.S. Application Data
(60) Provisional application No. 63/718,958, filed on Nov. 11, 2024.

(51) Int. Cl. H01L 21/768; H01L 23/532

(52) U.S. Cl. CPC H10W 20/047; H10W 20/033; H10W 20/056; H10W 20/425

(57) ABSTRACT

Interconnect structures in a microelectronic device and methods of forming the same are described. The method comprises processing a substrate comprising a dielectric layer disposed thereon, the dielectric layer having one or more features including an opening, a sidewall, a top surface, a bottom. The method includes forming a cobalt liner layer having a thickness in a range of from 5 Ångstroms to 20 Ångstroms on the sidewall, the top surface, and the bottom using a physical vapor deposition process. The method includes doping an external portion of the cobalt liner layer with carbon, the external portion of the cobalt liner layer having a thickness in a range of from 1 Ångstrom to 5 Ångstroms to form a lined feature. Copper is deposited into the lined feature.

### CROSS-REFERENCE TO RELATED APPLICATIONS

This application claims the benefit under 35 U.S.C. § 119(e) to U.S. Provisional Application No. 63/718,958, filed November 11, 2024, the entire content of which is incorporated herein by reference in its entirety.

### TECHNICAL FIELD

The present disclosure relates generally to methods of processing substrates, and specifically to methods for forming cobalt liners for metal interconnect structures such as copper interconnect structures.

### BACKGROUND

A semiconductor device such as an integrated circuit generally has electronic circuit elements such as transistors, diodes, and resistors fabricated integrally on a single body of semiconductor material. The various circuit elements are connected through conductive connectors called interconnect structures to form a complete circuit which can contain millions of individual circuit elements. Interconnect structures provide the electrical connections between the various electronic elements of an integrated circuit and form the connections between the circuit elements and the device's external contact elements, such as pins, for connecting the integrated circuit to other circuits. Typically, the interconnect structures form horizontal connections between electronic circuit elements, while conductive via plugs form vertical connections between the electronic circuit elements, resulting in layered connections.

Advances in semiconductor materials and processing techniques have resulted in reducing the overall size of the integrated circuit elements while increasing their number or density on a single body. However, as device nodes become smaller (for example, dimensions of about 22nm or less), challenges are presented, including degraded electromigration lifetimes and reduced device reliability. For example, copper is an excellent conductor and has been used in integrated circuits because copper components such as metal filled vias have excellent functionality at smaller sizes.

In existing devices, however, copper problematically diffuses into the surrounding areas or along a weak interface, unless contained, for example, in a liner. Certain liners are deficient and decrease the reliability of the interconnect structure. For example, liner material may be deposited atop a dielectric field of a substrate and within a feature such as a trench and/or a via and detrimentally impact the flow or reflow of copper material deposited thereon. Further, the liner material may problematically promote higher copper mobility upon the field of the substrate compared to the mobility of copper on the sidewalls of a feature leading to copper end of line agglomeration or overhangs of reflowed copper material at the corners of a feature such as a high-aspect ratio via.

Additionally, reduced or inhibited reflow of copper into a feature, such as a via including a liner, may promote voids or gaps formed in a copper conductive via plugs reducing device reliability. Moreover, existing liners may occupy too much space within a feature reducing the amount of conductive material such as copper in the feature and increasing device resistivity. Therefore, improved liners and methods for forming liners for copper are needed.

### SUMMARY OF THE DISCLOSURE

One aspect of the current disclosure pertains to a method for forming interconnect structures in a microelectronic device. In one embodiment, a method comprises processing a substrate comprising a dielectric layer disposed thereon, the dielectric layer including one or more features defined by a sidewall, a top surface, and a bottom. The method further comprises forming a cobalt liner layer on the sidewall, the top surface, and the bottom using a physical vapor deposition process to provide a lined feature. The cobalt liner layer has a thickness in a range of from 5 Ångstroms to 20 Ångstroms. The method further comprises doping an external portion of the cobalt liner layer with carbon. The external portion of the cobalt liner layer comprises a carbon dopant and has a thickness in a range of from 1 Ångstrom to 5 Ångstroms.

In some embodiments, the carbon dopant is diffused into the cobalt liner layer. In some embodiments, the carbon dopant is diffused into the cobalt liner layer using a chemical vapor deposition process. In some embodiments, the chemical vapor deposition process exposes the cobalt liner layer to a carbon-containing gas.

In some embodiments, the thin layer of the carbon dopant comprises forming a graphene layer on the cobalt liner layer. In some embodiments, the method further comprises diffusing the graphene layer into the cobalt liner layer. In some embodiments, the cobalt liner layer has a thickness in a range of from 5 Ångstroms to 15 Ångstroms, from 5 Ångstroms to 10 Ångstroms, or from 10 Ångstroms to 15 Ångstroms.

In some embodiments, the carbon dopant is present in a range of from 0.1% to 10 % by weight in the external portion or from 0.1% to 5 % by weight in the external portion. In some embodiments, the carbon dopant reduces a contact angle of the copper on the external portion, improving copper reflow compared to an undoped external portion.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIGS. 1A and 1B illustrate a dielectric layer before and after deposition of a liner layer and conductive fill material in accordance with one or more embodiments of the disclosure.

FIG. 2 illustrates a dielectric layer having an optional first layer, a liner layer, and conductive fill material in accordance with one or more embodiments of the disclosure; and

FIG. 3 illustrates is a cross-section view of a semiconductor device according to one or more embodiments of the disclosure;

FIG. 4 illustrates a cross-section view of the semiconductor device shown in FIG. 3 according to one or more embodiments of the disclosure; and

FIG. 5 is a flowchart illustrating a method according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways. Although specific reference is made to trenches in the following description, it is to be understood that the processes, films, and devices described herein may involve similar structures such as vias, through-silicon-vias (TSVs), dual damascene structures and the like.

The term "about" as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of about.

As used in this specification and the appended claims, the term "substrate" and "wafer" are used interchangeably, both referring to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A "substrate" as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor substrates. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term "substrate surface" is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms "precursor", "reactant", "reactive gas" and the like are used interchangeably to refer to any gaseous species that can react with the substrate surface, or with a film formed on the substrate surface. Reactants include precursors, which are used to deposit films on a surface and etchants, which are used to remove material from a surface. Some reactants act as both precursors and etchants, depending on process conditions. Chemical vapor deposition (CVD) is a process for depositing thin films by exposing a substrate to one or more volatile precursors, which react and/or decompose on the substrate surface.

As used herein, "physical vapor deposition (PVD)" refers to a variety of vacuum deposition methods which can be used to produce thin films and coatings on substrates including metals, ceramics, glass, and polymers. PVD is characterized by a process in which the material transitions from a condensed phase to a vapor phase and then back to a thin film condensed phase. In one or more embodiments, PVD is a process technology in which atoms of a material (e.g., aluminum, titanium nitride, etc.) are sputtered from a target of pure material, then deposited on the substrate to create a film on the substrate. In one or more embodiments, sputtering includes depositing a film using a process that includes bombarding a solid target with energetic particles and ejecting atoms from the solid target.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been described in great detail to avoid unnecessarily obscuring this description. Those of ordinary skill in the art, with the included description, will be able to implement appropriate functionality without undue experimentation.

Cobalt liners and methods for forming cobalt liners for copper interconnect structures are provided herein. As via dimensions become narrower, new challenges are raised in forming interconnect structures and copper fill of trenches and vias. Cobalt liner layers formed by chemical vapor deposition (CVD) are desired because such CVD-formed liner layers allow for better reflow of copper during copper reflow used for gap fill of the via of the interconnect structure. Current liner layers formed by chemical vapor deposition (CVD) typically need a liner thickness of up to 30 Ångstroms (30Å) to provide acceptable Cu reflow. Such a thick liner layer results in a very narrow via for Cu gap fill, which will increase the contact resistance (Rc) of the via.

According to one or more embodiments, it was advantageously discovered that using carbon as a dopant to diffuse or soak into PVD-deposited cobalt liner layer in an interconnect structure provides improved adhesion of the cobalt to the dielectric field and improved copper reflow compared to CVD-deposited cobalt. A very thin layer of cobalt with a thin external portion containing carbon that has been doped, diffused, or soaked into the cobalt layer provides beneficial results. In some embodiments, PVD-depositing a thin cobalt liner layer having a thickness in a range of 5-20 Ångstroms and having a thin, carbon-doped external portion with a thickness in a range of from 1-5 Ångstroms provides acceptable adhesion and excellent copper reflow.

By doping or diffusing 1-5 Ångstroms of carbon into the cobalt liner layer at the sidewall, the top surface, the bottom and on the via, the liner material may be formed to selectively alter the adhesion of copper deposited on the liner material and, thus, change the mobility of copper flowed over the liner material. In one or more embodiments, the adhesion of copper is selectively altered by altering the purity and/or thickness of the liner on a substrate or substrate field such as a dielectric field. By forming a very thin Co liner layer using a PVD process and doping it with carbon, where carbon is diffused into the thin Co liner layer, the reflow of copper deposited in a feature such as a trench and via to form a copper plug within the feature is improved. The inventive methods according to one or more embodiments may be utilized with any device nodes but may be particularly advantageous in device nodes of about 25 nanometer (nm) or less, for example about 3 nm to about 25 nm, such as 20nm, 14nm, 7nm, 5nm, or 3nm.

Advantageously, forming a thin cobalt liner layer using a PVD process and doping or infusing it with carbon to form a thin external portion containing carbon reduces the contact angle of copper in contact with the PVD-deposited cobalt. This improves copper (Cu) reflow performance and causes copper to more uniformly spread over single and dual damascene structures. This is particularly advantageous in dual damascene structures comprising a trench and a via.

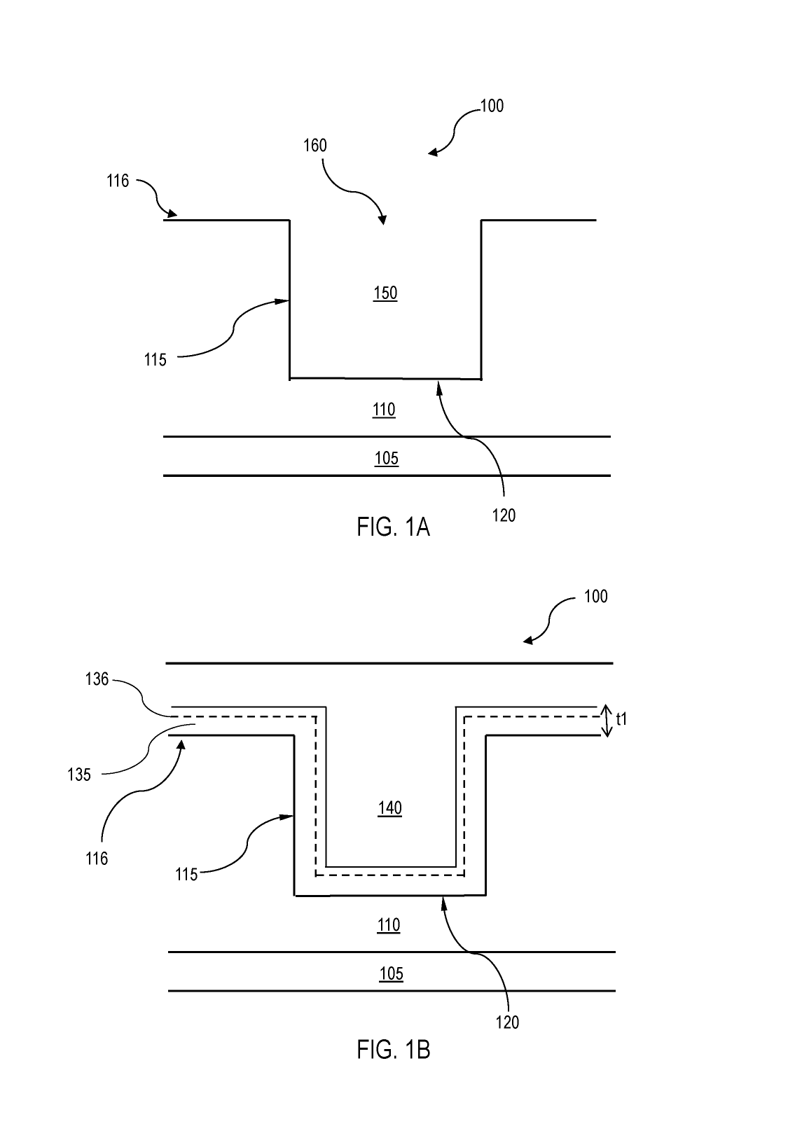

One aspect of the disclosure relates to a microelectronic device including an interconnect structure and a method of forming a microelectronic device comprising a substrate, a dielectric layer, a barrier layer, and a conductive material. FIG. 1A depicts an embodiment of a microelectronic device 100 comprising a substrate 105 and a dielectric layer 110 or dielectric field. The dielectric layer 110 or dielectric field is disposed upon the substrate 105, and the dielectric layer 110 or dielectric field has at least one feature formed therein. As used herein, the term "feature" refers to any intentional surface irregularity. Suitable examples of features include, but are not limited to, trenches which have a top, two sidewalls, and a bottom, peaks which have a top and two sidewalls, and vias which have a top and two sidewalls. Features can have any suitable aspect ratio (ratio of the depth of the feature to the width of the feature). In one or more embodiments, the aspect ratio is greater than or equal to about 1:1, 2:1, 3:1, 4:1, 5:1, 10:1, 15:1, 20:1, 25:1, 30:1, 35:1 or 40:1. In one or more embodiments, the feature formed in the dielectric layer 110 or dielectric field is a trench 150 defined by a trench bottom 120, sidewalls 115, and opening 160. A top surface 116 covers the dielectric layer 110 or dielectric field.

In one or more embodiments, the dielectric layer 110 or dielectric field is a low-k dielectric layer. As used herein according to one or more embodiments, a low-k dielectric layer refers to an insulating material that has a dielectric constant (k value) lower than that of silicon dioxide (~3.9), commonly used in interconnect structures. In certain embodiments, the dielectric layer 110 or dielectric field comprises SiOₓ. Further embodiments provide that the dielectric layer 110 or dielectric field with a k value in a range of 3.0 to 3.9. Examples of low-k dielectric materials include carbon-doped silicon oxide (e.g., SiOCH), silicon oxycarbide (SiOC), and organosilicate glass (OSG). In one or more embodiments, the low-k dielectric materials are porous to provide lower k values.

FIG. 1B shows the same microelectronic device 100 after deposition of a liner layer 135, which covers at least a portion of the sidewall 115, a top surface 116, and/or trench bottom 120. The liner layer 135 has a thickness t1 as shown. As shown in FIG. 1B, the liner layer 135 may cover the entirety of the sidewall 115, the top surface 116 and trench bottom 120. The liner layer 135 has an external portion 136 comprising a carbon dopant. The external portion 136 of the cobalt liner layer having a thickness in a range of from 1 Ångstrom to 5 Ångstroms to form a lined trench.

In one or more embodiments, the carbon dopant is diffused or otherwise doped into the external portion 136 of the liner layer by CVD or other suitable processes. For example, in one or more embodiments, doping cobalt with carbon includes diffusing carbon atoms into the cobalt lattice or alloy to form carbides (e.g., Co₂C). In one or more embodiments, carbon-containing gases are dissociated at elevated temperatures (e.g., 300–900°C), releasing atomic carbon that diffuses into the PVD-deposited cobalt liner layer. The carbon containing gas may comprise methane (CH₄), propane (C₃H₈), ethylene (C₂H₄), or acetylene (C₂H₂). In some embodiments, methane decomposes to provide carbon for interstitial diffusion, and in some embodiments in mixtures with hydrogen, promoting uniform carbon incorporation into the cobalt liner layer.

In one or more embodiments, a conductive fill material 140 fills at least a portion of the trench 150 lined with the liner layer 135. According to one or more embodiments, the conductive fill material comprises copper or a copper alloy. In further embodiments, the conductive fill material 140 also comprises manganese (Mn). In other embodiments, the conductive fill material 140 further comprises aluminum (Al).

Although the conductive fill material 140 in FIG. 1B is shown in direct contact with the liner layer 135, intermediate layers may be disposed between the conductive fill material 140 and the liner layer 135, such as adhesion layers or seeding layers. According to one or more embodiments, the microelectronic device further comprises an adhesion layer comprising one or more of ruthenium (Ru) and cobalt (Co). In addition to Ru and/or Co, the adhesion layer may comprise one or more dopants such as manganese (Mn), aluminum (Al), magnesium (Mg), chromium (Cr), niobium (Nb), titanium (Ti), or vanadium (V). In some embodiments, the adhesion layer comprises Ru and Mn. In other embodiments, the adhesion layer comprises Co and Mn.

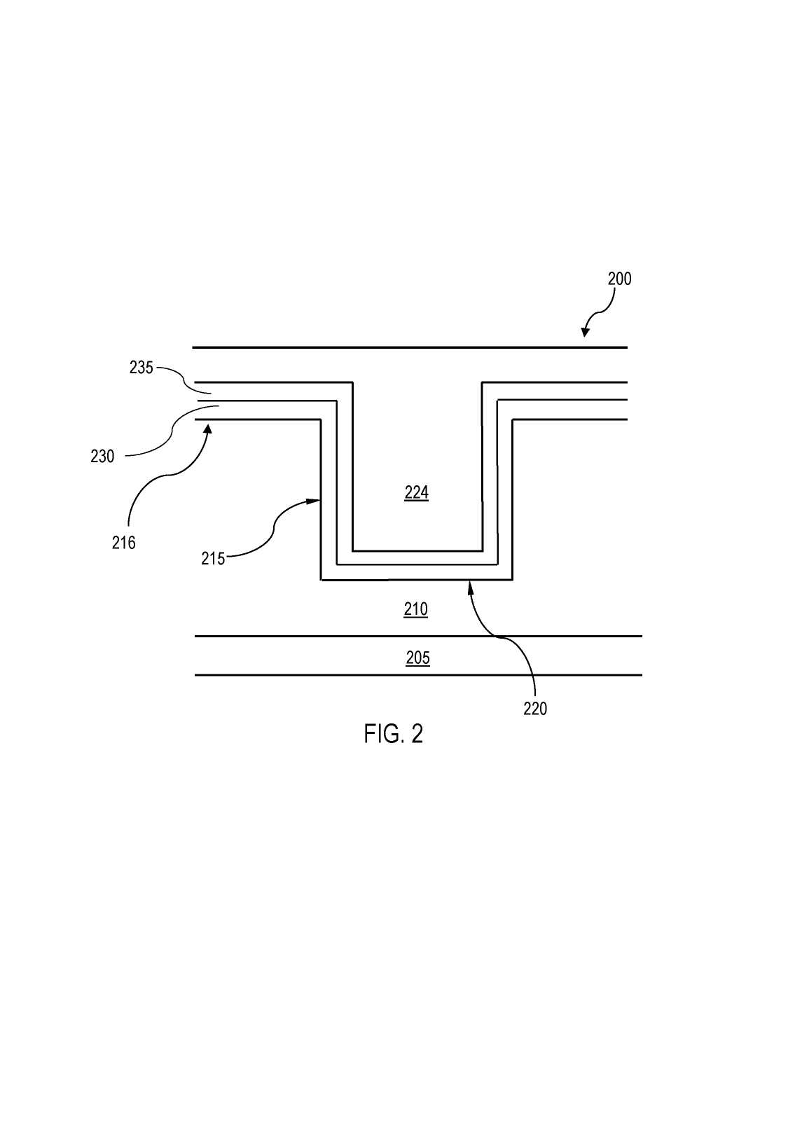

FIG. 2 illustrates a microelectronic device 200 with a substrate 205 and a dielectric layer 210 or dielectric field. The dielectric layer 210 or dielectric field has sidewalls 215, a top portion 216 and trench bottom 220, which are at least partially covered by a first layer 230. The first layer 230 may be an optional barrier layer comprising TaN and one or more dopants such as Ru, Cu, Co, Mn, Al, Mg, Nb, Ti, or V. In some embodiments, the first layer comprises TaN and Mn. In other embodiments, the first layer comprises TaN and one or more of Ru, Cu and Co.

A second layer 235 is disposed upon the first layer 230 and is a cobalt liner layer. A conductive fill material 224 is deposited in the remainder of the trench defined by sidewall 215 and trench bottom 220. According to one or more embodiments, the conductive fill material 224 comprises copper or a copper alloy.

In addition to the films described above, another aspect of the disclosure relates to a method for forming interconnect structures in a microelectronic device comprising processing a substrate with a dielectric layer disposed thereon, depositing an optional barrier layer upon the dielectric layer, depositing a cobalt liner layer upon the dielectric layer or the optional barrier layer and depositing a conductive material upon the cobalt liner layer. Prior to depositing the conductive fill material such as copper, the cobalt liner layer is treated to form an external portion comprising carbon. The carbon may be doped or diffused into the external portion of the cobalt liner layer.

The conductive material may be deposited in a variety of ways, including by an electroless deposition process, an electroplating (ECP) process, a CVD process or a PVD process. In certain embodiments, a first seed layer is deposited upon the barrier layer, and a bulk conductive layer is then formed upon the seed layer.

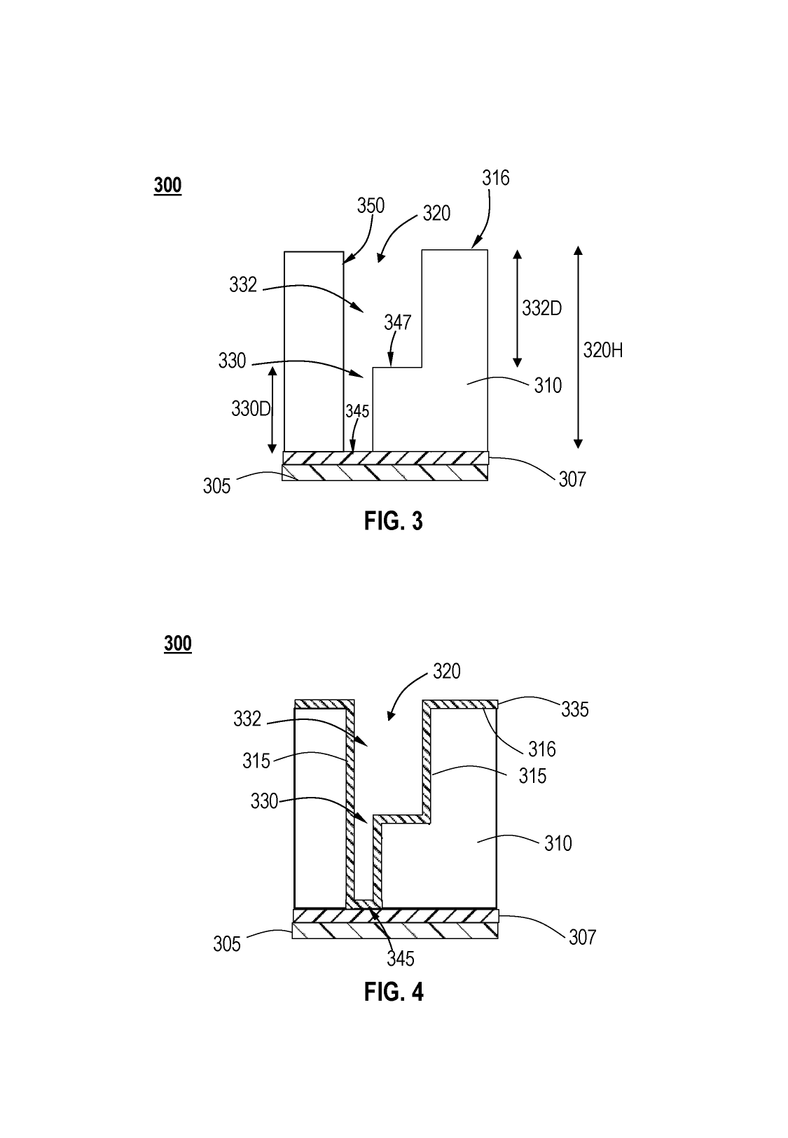

FIG. 3 is a cross-section view of an exemplary semiconductor device 300 during the processing method according to one or more embodiments of the disclosure. Referring to FIG. 3, a substrate 305 is provided. As used in this specification and the appended claims, the term "provided" means that the substrate 305 is made available for processing (e.g., positioned in a processing chamber). For illustrative purposes, FIG. 3 shows the semiconductor device 300 having a single feature 320. One skilled in the art, however, will understand that there can be more than one feature. As shown in FIG. 3, the feature 320 includes a first surface 345 and a second surface 350. In one or more embodiments, the first surface 345 is a bottom surface of the feature 320. In one or more embodiments, the second surface 350 is a sidewall of the feature 320. In one or more embodiments, the shape of the feature 320 can be any suitable shape including, but not limited to, trenches, vias that, when filled with metal, transfer current between layers, and lines that transfer current within the same device layer. It will be appreciated that in one or more embodiments, a metal layer 307 is a conductive layer that forms a metal line that transfers current within the same device layer.

In one or more embodiments, the feature 320 defines a gap in the dielectric layer 310. As used herein, the term "feature" refers to any intentional surface irregularity. Suitable examples of features include, but are not limited to, trenches which have a top, two sidewalls, and a bottom, peaks which have a top and two sidewalls. Features can have any suitable aspect ratio (ratio of the depth of the feature to the width of the feature). In one or more embodiments, the aspect ratio is greater than or equal to about 1:1, 2:1, 3:1, 4:1, 5:1, 10:1, 15:1, 20:1, 25:1, 30:1, 35:1 or 40:1.

In one or more embodiments, the feature 320 comprises a bottom portion or via 330 and a top portion or trench 332. In one or more embodiments, the bottom portion comprises a via 330, and the top portion comprises a trench 332.

In one or more embodiments, the metal layer 307 comprises a metal or a metallic material. The metal or metallic material can be any suitable metallic material. In one or more embodiments, the metallic materials are conductive materials. Suitable metallic materials include, but are not limited to, metals, conductive metal nitrides, conductive metal oxides, metal alloys, silicon, combinations thereof, and other conductive materials.

In one or more embodiments, the metal or metallic material may comprise any suitable metal. In one or more embodiments, the metal or metallic material is selected from one or more of copper (Cu), cobalt (Co), ruthenium (Ru), iridium (Ir), rhodium (Rh), molybdenum (Mo), tungsten (W), aluminum (Al), nickel (Ni), and platinum (Pt). In one or more embodiments, the metal or metallic material consists essentially of copper (Cu), cobalt (Co), ruthenium (Ru), iridium (Ir), rhodium (Rh), molybdenum (Mo), tungsten (W), aluminum (Al), nickel (Ni), or platinum (Pt). In one or more embodiments, the metal or metallic material consists essentially of copper (Cu), cobalt (Co), ruthenium (Ru), tungsten (W), or molybdenum (Mo). In one or more embodiments, the metallic material comprises or consists essentially of tungsten (W) or molybdenum (Mo).

In one or more embodiments, the bottom surface 345 of the at least one feature 320 is exposed. In one or more embodiments, the bottom surface 345 is a portion of the top surface of the metal layer 307, such that a portion of the metal layer 307 is exposed.

In one or more embodiments, the dielectric layer 310 can be any suitable material, including any of those described above with respect to the dielectric layer 110 of FIGS. 1A and 1B. For example, in one or more embodiments, the dielectric layer 310 comprises one or more of silicon oxide (SiOx), silicon nitride (SiN), silicon carbide (SiC), silicon carbonitride (SiCN), silicon oxynitride (SiON), silicon oxycarbide (SiOC), silicon oxycarbonitride (SiOCN), silicon boride (SiB), silicon borocarbonitride (SiBCN), silicon borocarbide (SiBC), silicon boron nitride (SiBN), and the like. In one or more embodiments, the dielectric layer 310 comprises one or more of silicon oxide (SiOx), silicon nitride (Si₃N₄), or silicon germanium (SiGe). In other embodiments, the dielectric layer 310 is any suitable low-k dielectric material.

Referring to FIG. 3, criteria for evaluating improved copper reflow is shown with respect to an interconnect structure 300 including a dual damascene structure with a bottom portion or via 330 and a top portion or trench 332 having a via depth 330D extending from a via bottom 345 to a via top or surface 347. A dual damascene structure refers to two features formed and filled with a conductive metal such as copper at once. For example, a trench 332 overlying a via 330 may both be filled with a single copper deposition step. The interconnect structure 300 includes a feature 320 having a feature height 320H extending from the first surface 345 or the via 330 bottom to the feature top 316 and a trench depth thickness 332D extending from a surface 347 or the via top to the feature top 316. The via 330 has a via depth 330D that extends from the first surface 345 or the via 330 bottom to the surface 347 or the via 330 top. In other words, the feature 320 includes the via 330 and the trench 332, and the feature height 320H extends from the first surface 345 or the via 330 bottom to the feature top 316. A value referred to herein as a "Bia" is equal to the feature height 320H minus the via depth 330D. In one or more embodiments, a smaller Bia value represents better copper spreading due to a reduced contact angle and better copper reflow. Experiments showed that PVD-formed thin cobalt liner layers that were in a range of 5-20 Ångstroms, 10-20 Ångstroms, 5-15, Ångstroms 10-15 Ångstroms, and 5-10 Ångstroms with a thin external portion of carbon dopant in range of 1-5 Ångstroms in thickness resulted lower Bia values than CVD-deposited cobalt liner layers.

FIG. 4 is a cross-section view of the semiconductor device 300 of FIG. 3 being processed according to the method of one or more embodiments. FIG. 4 illustrates the feature 320 in a dielectric layer 310 or dielectric field formed on a substrate 305 with a metal layer 307 on the substrate. The feature 320 includes the via 330 having a bottom defining a first surface 345 as the bottom of the feature 320. The feature 320 has at least one sidewall 315 and a top surface 316. In one or more embodiments, a PVD-deposited cobalt liner layer 335 lines the feature 320 on the top surface 316, the sidewalls 315, and the bottom or first surface 345. In one or more embodiments, a carbon dopant is diffused or otherwise doped into an external portion of the cobalt liner layer 335 by CVD or other suitable processes, as described above with respect to the liner layer 135 in FIGS. 1A and 1B. In one or more embodiments, the cobalt liner layer 335 has an external portion comprising a carbon dopant. The external portion of the cobalt liner layer 335 having a thickness in a range of from 1 Ångstrom to 5 Ångstroms to form a lined trench.

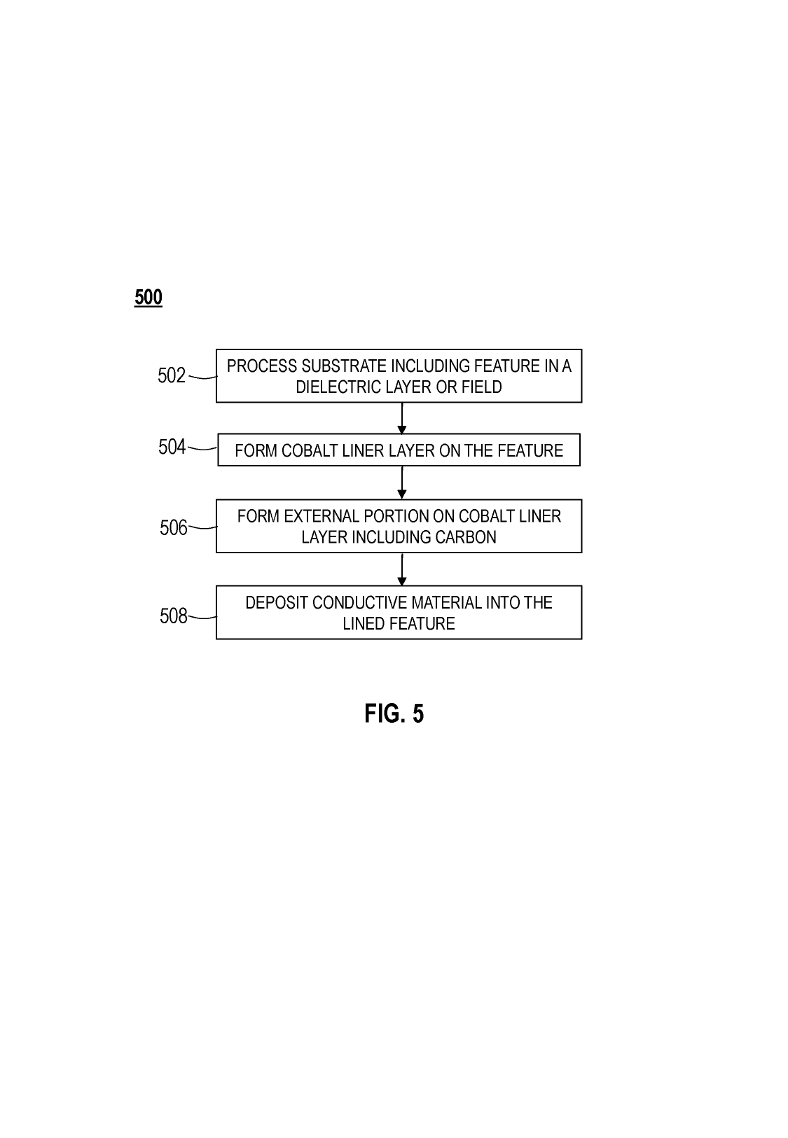

Referring now to FIG. 5, a method 500 for forming interconnect structures in a microelectronic device comprises at 502 processing a substrate comprising a dielectric layer disposed thereon, the dielectric layer or field including a trench defined by an opening, a sidewall, a top surface, a bottom and a via in the trench as shown herein. The method includes at 504 forming a cobalt liner layer using a physical vapor deposition process, the cobalt liner layer having a thickness in a range of from 5 Ångstroms to 20 Ångstroms on the sidewall, the top surface, the bottom and on the via to provide a lined trench and a lined via. At 506, the method includes forming on the cobalt liner layer an external portion comprising a carbon dopant, the external portion of the cobalt liner layer having a thickness in a range of from 1 Ångstrom to 5 Ångstroms. At 508, the method includes depositing a conductive material comprising copper into the lined trench and the lined via.

Reference throughout this specification to "one embodiment," "certain embodiments," "one or more embodiments" or "an embodiment" means that a particular feature, structure, material, or characteristic described in connection with the embodiment is included in at least one embodiment of the disclosure. Thus, the appearances of the phrases such as "in one or more embodiments," "in certain embodiments," "in one embodiment" or "in an embodiment" in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method for forming interconnect structures in a microelectronic device, the method comprising:
processing a substrate comprising a dielectric layer disposed thereon, the dielectric layer including a feature defined by a sidewall, a top surface, and a bottom;
forming a cobalt liner layer on the sidewall, the top surface, and the bottom using a physical vapor deposition process to provide a lined feature, the cobalt liner layer having a thickness in a range of from 5 Ångstroms to 20 Ångstroms;
forming an external portion on the cobalt liner layer, the external portion of the cobalt liner layer comprising a carbon dopant and having a thickness in a range of from 1 Ångstrom to 5 Ångstroms; and
depositing a conductive material comprising copper into the lined feature.

2. The method of claim 1, wherein the carbon dopant is diffused into the cobalt liner layer.

3. The method of claim 2, wherein the carbon dopant is diffused into the cobalt liner layer using a chemical vapor deposition process.

4. The method of claim 3, wherein the chemical vapor deposition process exposes the cobalt liner layer to a carbon-containing gas.

5. The method of claim 4, wherein the carbon-containing gas comprises methane.

6. The method of claim 1, wherein forming the external portion comprising the carbon dopant comprises forming a graphene layer on the cobalt liner layer.

7. The method of claim 6, further comprising diffusing the graphene layer into the cobalt liner layer.

8. The method of claim 1, wherein the cobalt liner layer has a thickness in a range of from 5 Ångstroms to 15 Ångstroms.

9. The method of claim 1, wherein the cobalt liner layer has a thickness in a range of from 5 Ångstroms to 10 Ångstroms.

10. The method of claim 1, wherein the cobalt liner layer has a thickness in a range of from 10 Ångstroms to 15 Ångstroms.

11. The method of claim 1, wherein the carbon dopant is present in a range of from 0.1% to 10 % by weight in the external portion of the cobalt liner layer.

12. The method of claim 1, wherein the carbon dopant is present in a range of from 0.1% to 5 % by weight in the external portion of the cobalt liner layer.

13. The method of claim 11, wherein the carbon dopant reduces a contact angle of the copper on the external portion of the cobalt liner layer, improving copper reflow compared to an undoped external portion.

14. The method of claim 1, wherein the feature comprises one via and one trench and forms a dual damascene structure.

15. A semiconductor device comprising:
a substrate comprising a dielectric layer disposed thereon, the dielectric layer including a feature defined by a sidewall, a top surface, and a bottom; and
a cobalt liner layer on the sidewall, the top surface, and the bottom of the feature, the cobalt liner layer having a thickness in a range of from 5 Ångstroms to 20 Ångstroms, wherein an external portion of the cobalt liner layer comprises a carbon dopant and has a thickness in a range of from 1 Ångstrom to 5 Ångstroms.

16. The semiconductor device of claim 15, further comprising a conductive fill material in the feature on the cobalt liner layer.

17. The semiconductor device of claim 16, wherein the conductive fill material comprises copper.

18. The semiconductor device of claim 15, wherein the cobalt liner layer has a thickness in a range of from 5 Ångstroms to 15 Ångstroms.

19. The semiconductor device of claim 15, wherein the cobalt liner layer has a thickness in a range of from 5 Ångstroms to 10 Ångstroms.

20. The semiconductor device of claim 15, wherein the carbon dopant is present in a range of from 0.1% to 10 % by weight in the external portion of the cobalt liner layer.
